(19) United States
(12) Patent Application Publication
(10) Pub. No.: US 2025/0056166 A1
(43) Pub. Date: Feb. 13, 2025

(54) PIEZOELECTRIC FILM DEVICE, TRANSDUCER, AND METHOD FOR MANUFACTURING PIEZOELECTRIC FILM DEVICE

(71) Applicant: ROHM CO., LTD., Kyoto-shi (JP)

(72) Inventor: Tatsuya SUZUKI, Kyoto-shi (JP)

(21) Appl. No.: 18/797,914

(22) Filed: Aug. 8, 2024

(30) Foreign Application Priority Data
Aug. 10, 2023 (JP) 2023-131327

(51) Int. Cl. H04R 17/00

(52) U.S. Cl. CPC H04R 17/00; H04R 2201/003

(57) ABSTRACT

A piezoelectric film device 90 includes a substrate 80 having a lower surface 81 and an upper surface 82 facing opposite directions, a support portion 41 supporting the lower surface 81 and fixed to an installation surface, and a piezoelectric film 12 provided on the upper surface 82 and displaced in a vertical direction together with the substrate 80 in response to application of a bias voltage and a drive voltage, in which the substrate 80 has a first region 81x supported by the support portion 41 and a second region 81y not supported by the support portion 41 as regions of the lower surface 81, and in a state where the bias voltage and the drive voltage are not applied, the substrate 80 is formed to be warped such that the second region 81y is located closer to the installation surface than the first region 81x.

### CROSS REFERENCE TO RELATED APPLICATIONS

This application claims the benefit of priority to Japanese Patent Application No. 2023-131327 filed on Aug. 10, 2023. The entire contents of the above-identified application are hereby incorporated by reference.

### TECHNICAL FIELD

The present disclosure relates to a piezoelectric film device, a transducer, and a method for manufacturing a piezoelectric film device.

### BACKGROUND

Japanese Unexamined Patent Publication No. 2021-52305 discloses a transducer including a support having a cavity, a vibrating film provided to face the cavity and capable of vibrating in a facing direction, and a piezoelectric element formed on a front surface of the vibrating film on a side opposite to the cavity, in which a cantilever having a fixed end and a free end is formed.

### BRIEF DESCRIPTION OF DRAWINGS

FIG. 1 is a plan view of a sound-wave generating device according to the present embodiment;

FIG. 2 is a bottom view of the sound-wave generating device according to the present embodiment;

FIG. 3 is a longitudinal sectional view of the sound-wave generating device taken along line III-III in FIG. 1, and is a longitudinal sectional view of the sound-wave generating device to which a bias voltage is not applied;

FIG. 4 is a longitudinal sectional view of the sound-wave generating device to which a bias voltage is applied;

FIG. 5 is a longitudinal sectional view of the sound-wave generating device to which a bias voltage and a drive voltage are applied;

FIG. 6A is a view showing a displacement amount when a bias voltage is set to 0 and a drive voltage is applied, and FIG. 6B is a view showing a displacement amount when a bias voltage is set to V_{α} and a drive voltage is applied;

FIG. 7 is a longitudinal sectional view showing a step of a manufacturing procedure of the sound-wave generating device;

FIG. 8 is a longitudinal sectional view showing a step performed subsequent to the step shown in FIG. 7;

FIG. 9 is a longitudinal sectional view showing a step performed subsequent to the step shown in FIG. 8;

FIG. 10 is a longitudinal sectional view showing a step performed subsequent to the step shown in FIG. 9;

FIG. 11 is a longitudinal sectional view showing a step performed subsequent to the step shown in FIG. 10;

FIG. 12 is a longitudinal sectional view showing a step performed subsequent to the step shown in FIG. 11;

FIG. 13 is a longitudinal sectional view showing a step performed subsequent to the step shown in FIG. 12;

FIG. 14 is a longitudinal sectional view showing a step performed subsequent to the step shown in FIG. 13;

FIG. 15A is a view describing a sound-wave generating device according to a comparative example, and FIG. 15B is a view describing a sound-wave generating device according to another comparative example;

FIG. 16 is a view showing an example of a sound pressure level according to a state at the time of applying a bias voltage;

FIGS. 17A and 17B are views describing additional actions and effects of the sound-wave generating device according to the present embodiment;

FIG. 18 is a plan view of a sound-wave generating device according to a modification example;

FIG. 19 is a longitudinal sectional view of the sound-wave generating device taken along line XIX-XIX in FIG. 18;

FIG. 20 is a plan view of a sound-wave generating device according to a modification example;

FIG. 21 is a perspective view of the sound-wave generating device shown in FIG. 20 as viewed from above; and

FIG. 22 is a perspective view of the sound-wave generating device shown in FIG. 20 as viewed from below.

### DETAILED DESCRIPTION

Hereinafter, embodiments will be described with reference to the drawings. In the description, the same elements or elements having the same function are denoted by the same reference numerals, and redundant description will be omitted.

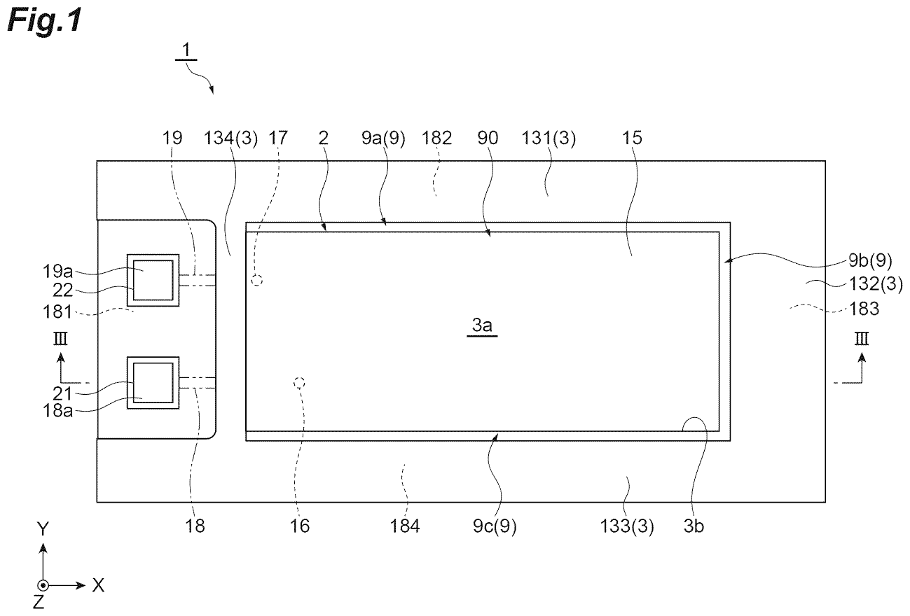

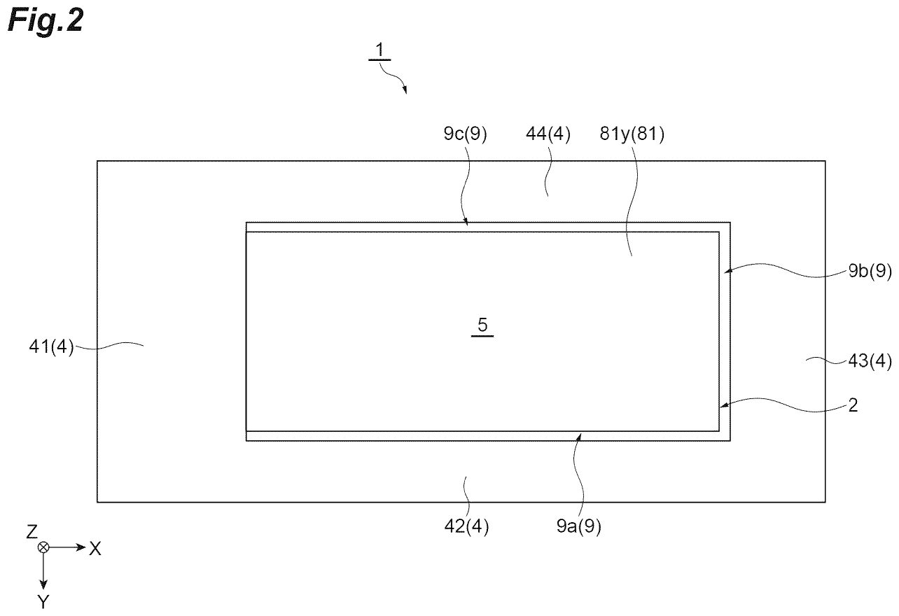

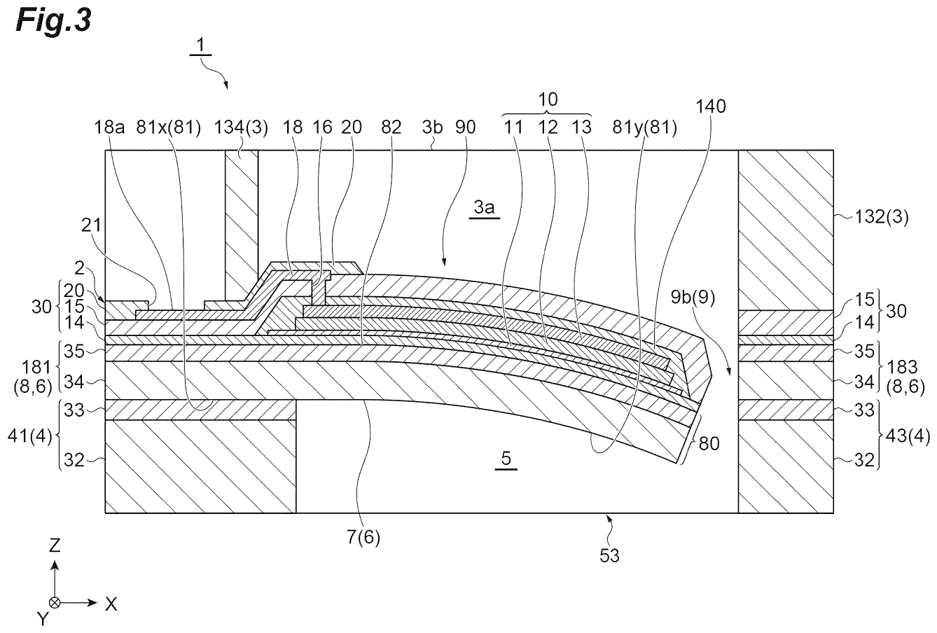

FIG. 1 is a plan view of a sound-wave generating device (transducer) according to the present embodiment. FIG. 2 is a bottom view of the sound-wave generating device according to the present embodiment. FIG. 3 is a longitudinal sectional view of the sound-wave generating device taken along line III-III in FIG. 1, and is a longitudinal sectional view of the sound-wave generating device to which a bias voltage is not applied.

A sound-wave generating device 1 is, for example, a device including one piezoelectric film device 90. The sound-wave generating device 1 is a device generating a sound wave by vibrating air by vibration of a piezoelectric film of the piezoelectric film device 90. The sound-wave generating device 1 may be, for example, a speaker, or may be an ultrasonic transducer generating an ultrasonic wave. The speaker and the ultrasonic transducer in this case both vibrate air and can operate with substantially the same structure, but the frequency range used is different between an audible range and an ultrasonic range. The piezoelectric film device 90 is, for example, MEMS (Micro Electro Mechanical Systems) device using piezoelectric properties. In the following description, it is assumed that the sound-wave generating device 1 is a speaker.

As shown in FIG. 1 to FIG. 3, the sound-wave generating device 1 includes a substrate assembly 2 and subframe 3. The substrate assembly 2 includes a supporting substrate 4, a vibrating film formation layer 6, and a piezoelectric element 10.

The supporting substrate 4 has a quadrilateral shape (substantially rectangular shape) in plan view. In the following description, a longitudinal direction of the supporting substrate 4 having a substantially rectangular shape in plan view is referred to as an X direction, a lateral direction thereof is referred to as a Y direction, and a direction intersecting the X direction and the Y direction (that is, a thickness direction of the supporting substrate 4) is referred to as a Z direction. In the Z direction, a direction in which the piezoelectric element 10 is located with reference to the supporting substrate 4 is referred to as “upper”, and a direction in which the supporting substrate 4 is located with reference to the piezoelectric element 10 is referred to as “lower”.

The supporting substrate 4 is made, for example, from a part of a SOI substrate. Specifically, the SOI substrate includes a silicon (Si) substrate 32 as a support layer, an oxide film layer 33 as a BOX layer formed on a front surface of the preceding, and a silicon (Si) layer 34 as an active layer formed on a front surface of the preceding. In the configuration according to the present embodiment, a silicon oxide (SOI₂) film 35 is formed on the front surface of the silicon layer 34. Further, the supporting substrate 4 includes, among the above, the silicon substrate 32 and the oxide film layer 33 formed on the front surface thereof. A thickness of the supporting substrate 4 is about 380 μm.

The supporting substrate 4 has a cavity (hollow space) 5 formed by a through hole penetrating through in the Z direction. The cavity 5 has a rectangular parallelepiped shape with an opening portion 53 having a quadrangular shape on the lower surface (bottom surface) side of the cavity 5 as a bottom surface in plan view.

The supporting substrate 4 includes a support portion 41, a first portion 42, a second portion 43, and a third portion 44. The support portion 41 supports a lower surface 81 of the substrate 80 and is fixed to an installation surface as described later. The support portion 41 and the second portion 43 extend along the Y direction so as to sandwich the cavity 5 therebetween in the X direction. The first portion 42 and the third portion 44 extend along the X direction so as to sandwich the cavity therebetween in the Y direction. That is, the support portion 41, the first portion 42, the second portion 43, and the third portion 44 are provided to surround the cavity 5. In the following description, in the X direction, a direction in which the second portion 43 is located with reference to the support portion 41 is referred to as “front”, and a direction in which the support portion 41 is located with reference to the second portion 43 is referred to as “rear”.

The vibrating film formation layer 6 is formed on the supporting substrate 4. The vibrating film formation layer 6 is constituted of a laminated film in which the silicon layer 34 and the silicon oxide film 35 are laminated in that order from the supporting substrate 4 side. A film thickness of the silicon layer 34 is, for example, about 20 μm and a film thickness of the silicon oxide film 35 is, for example, about 0.5 μm.

The vibrating film formation layer 6 includes a vibrating film 7 facing the cavity 5 and a frame portion 8 formed to surround the cavity 5 in plan view. The vibrating film 7 has a rectangular shape substantially similar to the cavity 5 in plan view. The frame portion 8 includes a support frame 181 (see FIG. 3), a first portion 182 (see FIG. 1), a second portion 183 (see FIG. 3), and a third portion 184 (see FIG. 1). The support frame 181 constitutes a part of the substrate 80 described later and is supported by the support portion 41. The first portion 182 is formed along the X direction on the first portion 42 of the supporting substrate 4 and is supported by the first portion 42. The second portion 25 183 is formed along the Y direction on the second portion 43 of the supporting substrate 4 and is supported by the second portion 43. The third portion 184 is formed along the X direction on the third portion 44 of the supporting substrate 4 and is supported by the third portion 44.

In a manufacturing process, a slit 9 is formed before the cavity 5 is formed in the supporting substrate 4 (details will be described later). In a step in which the slit 9 is formed, the slit 9 is formed to penetrate through the vibrating film 7 from a front surface of an interlayer insulating film 15, which is described later, formed on the vibrating film formation layer 6 and reach the supporting substrate 4.

As shown in FIG. 1, the slit 9 is constituted of a first portion 9a and a third portion 9c formed along the X direction and a second portion 9b formed along the Y direction. The first portion 9a is formed along a side extending in the X direction on one end side in the Y direction of the cavity 5. The third portion 9c is formed along a side extending in the X direction on the other end side in the Y direction of the cavity 5. The second portion 9b is formed to connect a front end portion of the first portion 9a and a front end portion of the third portion 9c.

The piezoelectric element 10 is formed after a hydrogen barrier film 14 is formed on the vibrating film formation layer 6. Specifically, the piezoelectric element 10 is formed such that at least a part thereof is disposed on the vibrating film 7. In the present embodiment, the entire piezoelectric element 10 is disposed on the vibrating film 7. The piezoelectric element 10 includes a lower electrode 11 formed on the vibrating film 7, a piezoelectric film 12 formed on the lower electrode 11, and an upper electrode 13 formed on the piezoelectric film 12. Furthermore, a hydrogen barrier film 140 is formed on the upper electrode 13 of the piezoelectric element 10.

The lower electrode 11 and the upper electrode 13 are constituted, for example, of a thin metal film having conductivity of platinum, molybdenum, iridium, titanium, or the like. A film thickness of the lower electrode 11 is, for example, about 200 nm, and a film thickness of the upper electrode 13 is, for example, about 80 nm.

The piezoelectric film 12 is constituted, for example, of lead zirconate titanate (PZT). The piezoelectric film 12 may be constituted of a niobium-doped lead zirconate titanate (PNZT) film, a lanthanum-doped lead zirconate titanate (PLZT) film, a barium strontium titanate (BST) film, a bismuth strontium tantalate (SBT) film, a barium strontium niobate (SBN) film, a lithium niobate (LiNbO3) film, a barium titanate (TiBaO3) film, a lanthanum strontium copper oxide (LSCO) film, a potassium dihydrogen phosphate (KDP) film, a potassium tantalum niobate (KTN) film, a lead magnesium niobate titanate (PMN-PT)-based ceramic film, a lead zinc niobate titanate (PZN-PT)-based ceramic film, aluminum nitride (AIN), zinc oxide (ZnO), lead titanate (PbTiO₃), or the like. A film thickness of the piezoelectric film 12 is, for example, about 2 μm.

The hydrogen barrier film 14 is formed on the vibrating film 7 and the frame portion 8 constituting the vibrating film formation layer 6. The hydrogen barrier film 14 is formed on the vibrating film 7 so as to cover the piezoelectric element 10. The hydrogen barrier film 14 is constituted, for example, of Al₂O₃ (alumina). A thickness of the hydrogen barrier film 14 is about 20 nm to 100 nm. The hydrogen barrier film 14 is provided to prevent characteristic degradation of the piezoelectric film 12 due to hydrogen reduction.

The interlayer insulating film 15 is laminated on the hydrogen barrier film 14. The interlayer insulating film 15 is constituted, for example, of a film containing tetraethoxysilane (TEOS) (TEOS film). The interlayer insulating film 15 may be constituted of silicon nitride (SiN) or the like. A thickness of the interlayer insulating film 15 is, for example, about 0.2 μm to 1.5 μm.

An upper wiring 18 and a lower wiring 19 (see FIG. 1) are formed on the interlayer insulating film 15. The upper wiring 18 and the lower wiring 19 are provided at the end portion (rear end portion) in the X direction on a side where the support portion 41 is provided in the interlayer insulating film 15. The upper wiring 18 and the lower wiring 19 extend in the X direction at an interval in the Y direction. The upper wiring 18 and the lower wiring 19 may be constituted of a metal material containing Al (aluminum). A thickness of each of the upper wiring 18 and the lower wiring 19 is, for example, about 1 μm.

A front end portion of the upper wiring 18 is disposed above a rear end portion of the upper electrode 13. A contact hole 16 (see FIG. 1 and FIG. 3) penetrating continuously through the hydrogen barrier film 14 and the interlayer insulating film 15 is formed between the upper wiring 18 and the upper electrode 13. The front end portion of the upper wiring 18 enters into the contact hole 16 and is connected to the rear end portion of the upper electrode 13 inside the contact hole 16. An upper pad portion 18a having a wide width is formed at a rear end portion of the upper wiring 18. The upper pad portion 18a is disposed on the support frame 181 of the frame portion 8.

A front end portion of the lower wiring 19 is disposed above a rear end portion of the lower electrode 11. A contact hole 17 (see FIG. 1) penetrating continuously through the hydrogen barrier film 14 and the interlayer insulating film 15 is formed between the lower wiring 19 and the lower electrode 11. The front end portion of the lower wiring 19 enters into the contact hole 17 and is connected to the rear end portion of the lower electrode 11 inside the contact hole 17. A lower pad portion 19a having a wide width is formed at a rear end portion of the lower wiring 19. The lower pad portion 19a is disposed on the support frame 181 of the frame portion 8.

A passivation film 20 is formed on the interlayer insulating film 15 so as to cover the upper wiring 18 and the lower wiring 19. The passivation film 20 is constituted, for example, of a film containing tetraethoxysilane (TEOS) (TEOS film). The passivation film 20 may be constituted of silicon nitride (SiN) or the like. A thickness of the passivation film 20 is, for example, about 0.1 μm to 1.0 μm. In the passivation film 20, an upper pad opening 21 exposing a part of the upper pad portion 18a and a lower pad opening 22 exposing a part of the lower pad portion 19a (see FIG. 1) are formed. Hereinafter, the hydrogen barrier film 14, the interlayer insulating film 15, and the passivation film 20 may be collectively referred to as an insulating film 30.

In the substrate assembly 2, the substrate 80 having a rectangular shape in plan view is formed by the vibrating film 7 and the support frame 181 of the frame portion 8. The substrate 80 has the lower surface 81 (first surface) and an upper surface 82 (second surface) facing opposite directions. The lower surface 81 is a lower surface of the silicon layer 34, and the upper surface 82 is an upper surface of the silicon oxide film 35. The substrate 80 has a first region 81x supported by the support portion 41 and a second region 81y not supported by the support portion 41 as regions of the lower surface 81.

The first region 81x is supported by an upper surface of the oxide film layer 33 of the support portion 41 and fixed to the upper surface. The state of being supported by (the upper surface of the oxide film layer 33 of) the support portion 41 means, for example, a state of being in contact with the support portion 41 directly or via any member and being supported by the support portion 41. The state of being fixed to the support portion 41 means, for example, a state of being fixed to the support portion 41 directly or via any member and being not separated from the support portion 41. The state of being fixed to the support portion 41 may mean, for example, a state of being integrated with the support portion 41 or being bonded to the support portion 41. Note that, in the substrate 80, the entire region supported by the support portion 41 is not necessarily fixed to the support portion 41, and only a part of the supported region may be fixed to the support portion 41.

Further, the piezoelectric film 12 is provided on the upper surface 82 of the substrate 80 (that is, the upper surface of the silicon oxide film 35) with the lower electrode 11 interposed therebetween, and is displaced in a vertical direction (first direction) together with the substrate 80 in response to application of a bias voltage and a drive voltage described later. Such a substrate 80, the support portion 41, and the piezoelectric element 10 may be collectively referred to as the piezoelectric film device 90.

The piezoelectric film device 90 has a cantilever structure in which a rear end portion of the substrate 80 supported by the support portion 41 is a fixed end and a front end portion of the substrate 80 is a free end. In the piezoelectric film device 90, the piezoelectric film 12 is displaced in the vertical direction in response to application of a bias voltage and a drive voltage, and the free end side (front end portion side) of the substrate 80 is displaced in the vertical direction together with the piezoelectric film 12.

As shown in FIG. 3, in a state where a bias voltage and a drive voltage are not applied to the piezoelectric film 12, the substrate 80 is formed to be warped such that the second region 81y is located below the first region 81x (on the installation surface side in the vertical direction). That is, in the piezoelectric film device 90 having a cantilever structure, at a position (neutral position) in a state where the piezoelectric film 12 is not deformed by an input electric signal, the free end side of the substrate 80 is held in a warped posture so as to hang down toward the cavity 5 side with respect to the fixed end side. In a state where a bias voltage and a drive voltage are not applied to the piezoelectric film 12, a difference in position in the vertical direction between front end portions of the first region 81x and the second region 81y may be 100 μm or more and 500 μm or less, for example, in a case where a length of the piezoelectric film device 90 having a cantilever structure in the X direction is about 3 mm. Furthermore, a difference in position between the first region 81x and the second region 81y may be equal to or larger than a thickness of the silicon layer 34 constituting the substrate 80.

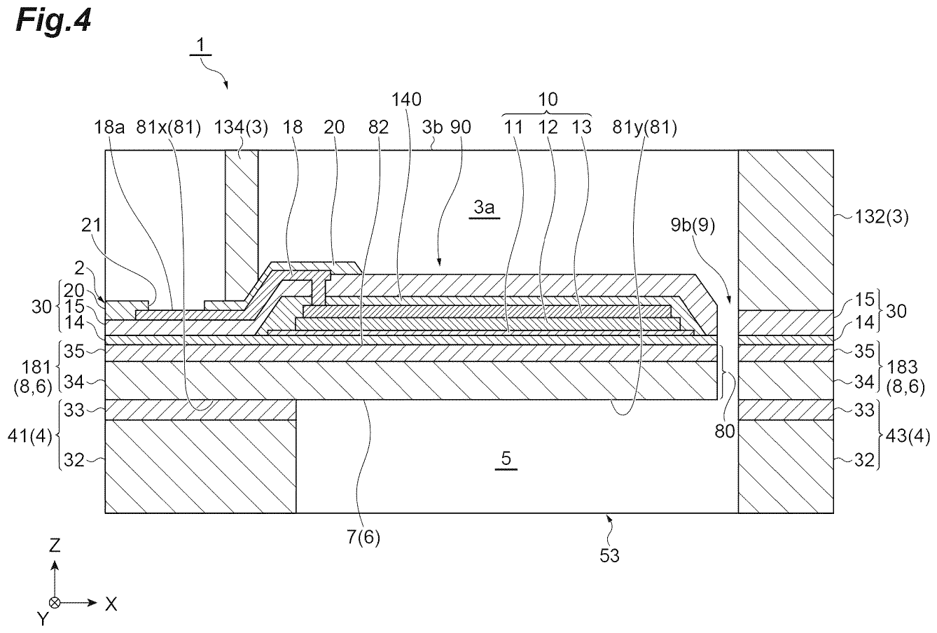

Further, as shown in FIG. 4, in a state where only the bias voltage is applied to the piezoelectric film 12 (the bias voltage is applied and the drive voltage is not applied), the difference in position in the vertical direction between front end portions of the first region 81x and the second region 81y may be 50 μm or less (that is, substantially horizontal). In a state where only the bias voltage is applied to the piezoelectric film 12 (the bias voltage is applied and the drive voltage is not applied), the difference in position in the vertical direction between front end portions of the first region 81x and the second region 81y may be equal to or less than the thickness of the substrate 80 in the vertical direction (that is, substantially horizontal).

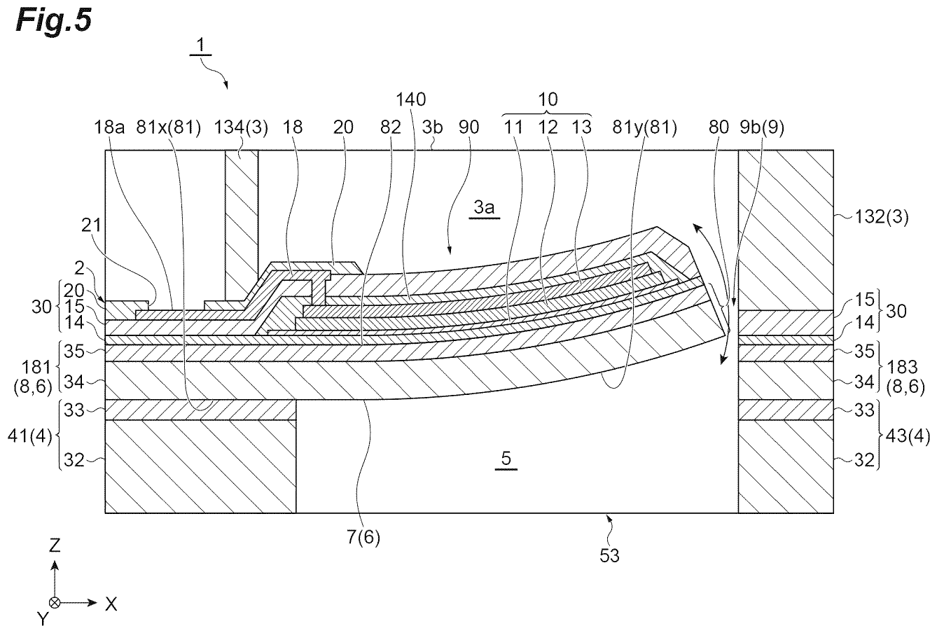

Further, when the drive voltage is applied from a state where the substrate 80 shown in FIG. 4 is substantially horizontal, the free end side (front end portion side) of the substrate 80 is displaced in the vertical direction (see FIG. 5). At the time of applying the drive voltage, the bias voltage is invariable (fixed value).

Due to the characteristics of the piezoelectric film 12, in order to increase vibration (sound) determined by the displacement amount thereof, it is preferable to operate the piezoelectric film 12 only on the positive side or only on the negative side without straddling 0 V in an operating voltage range. In the configuration according to the present embodiment, the bias voltage is applied so that the operating voltage range of the piezoelectric film 12 is only on the positive side. Specifically, the bias voltage is set to half or more of the maximum drive voltage, and the operating voltage range of the piezoelectric film 12 is only on the positive side.

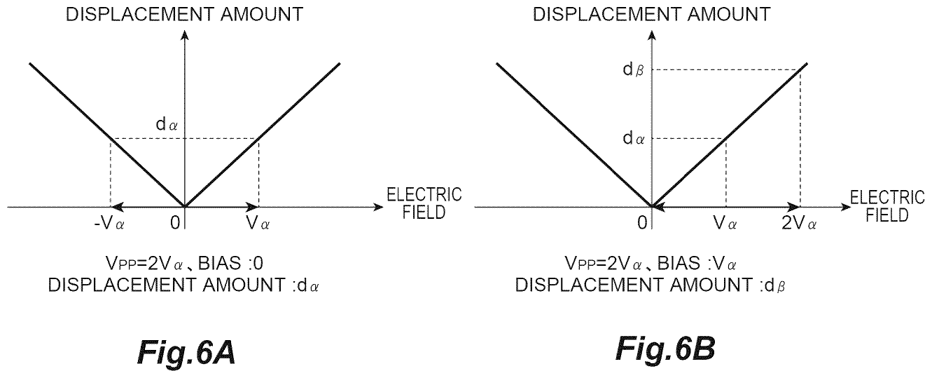

FIG. 6A is a view showing a displacement amount when a bias voltage is set to 0 and a drive voltage is applied, and FIG. 6B is a view showing a displacement amount when a bias voltage is set to V_{α} a and a drive voltage is applied. As shown in FIG. 6A, in a case where the bias voltage is 0 and the drive voltage (applied electric field) is 2V_{α}, the operating voltage range is −V_{α} to +V_{α} with 0 V as the center, so that the displacement amount of the piezoelectric film 12 is small, which is d_{α} here. On the other hand, as shown in FIG. 6B, in a case where the bias voltage is V_{α} and the drive voltage (applied electric field) is 2V_{α}, the operating voltage range is 0 to 2V_{α} with V_{α} as the center. In this case, the displacement amount of the piezoelectric film 12 is d_{β} larger than d_{α} as compared with a case where the bias voltage is 0. As described above, even when Vₚₚ is the same, by appropriately setting the bias voltage, the displacement amount of the piezoelectric film 12 can be increased, and the vibration (sound) of the sound-wave generating device 1 can be increased.

Further, in the sound-wave generating device 1, a warpage amount of the substrate 80 (specifically, an amount of sag in the downward direction on the free end side of the substrate 80) in a state where a bias voltage and a drive voltage are not applied is set such that the substrate 80 becomes substantially horizontal in a state where a bias voltage is applied and a drive voltage is not applied. Thereby, the substrate 80 can be appropriately brought into a horizontal state at the timing when the application of the drive voltage is started (state where only the bias voltage is applied). As is clear from comparison of the respective states in FIG. 3 to FIG. 5, the state where the substrate 80 is horizontal is a state where a gap between the front end portion (end portion on the free end side) of the substrate 80 and the second portion 183 of the frame portion 8 and the like is minimized. With this state as a reference, the substrate 80 moves up and down in response to the application of the drive voltage, whereby the size of the gap during the up and down operation of the substrate 80 can be minimized, and the influence of sound leakage can be suppressed.

As shown in FIG. 1 and FIG. 3, the subframe 3 is constituted, for example, of a silicon substrate in which a silicon oxide film (not shown) is formed on a lower surface and an upper surface. The subframe 3 is disposed on the substrate assembly 2 so as to cover the piezoelectric film device 90. The subframe 3 is bonded to the frame portion 8 via an adhesive (not shown). The subframe 3 includes a first portion 131, a second portion 132, a third portion 133, and a connecting portion 134, all of which are erected in the Z direction. As shown in FIG. 1, the first portion 131 is formed along the X direction above the first portion 182 of the frame portion 8. The second portion 132 is formed along the Y direction above the second portion 183 of the frame portion 8. The third portion 133 is formed along the X direction above the third portion 184 of the frame portion 8. The connecting portion 134 is formed along the Y direction above the support frame 181. A region surrounded by the first portion 131, the second portion 132, the third portion 133, and the connecting portion 134 is a region immediately above the cavity 5, and is a housing recess 3a for housing the piezoelectric film device 90. A through hole 3b functioning as an outlet for sound generated by the sound-wave generating device 1 is formed above the housing recess 3a.

Since the above-described subframe 3 is provided, air leakage is prevented, and sound characteristics in the sound-wave generating device 1 are improved. Furthermore, since the subframe 3 is provided, the piezoelectric film device 90 having a cantilever structure is protected. Furthermore, since the subframe 3 is provided, the rigidity of the chip is improved.

In such a sound-wave generating device 1, when a voltage is applied between the lower electrode 11 and the upper electrode 13, the piezoelectric film 12 is deformed by the inverse piezoelectric effect. Thereby, the piezoelectric film 12 and the substrate 80 constituting the piezoelectric film device 90 are deformed with the first region 81x, which is a fixed end, as a fulcrum. When a voltage corresponding to a sound signal is continuously applied between the lower electrode 11 and the upper electrode 13, the piezoelectric film device 90 vibrates such that the free end side of the substrate 80 reciprocates in the vertical direction. Air around the piezoelectric film device 90 vibrates by such vibration of the piezoelectric film device 90 to generate a sound wave. The sound wave propagates to the external space through the through hole 3b of the subframe 3. Note that, the sound wave is also generated in the opposite direction.

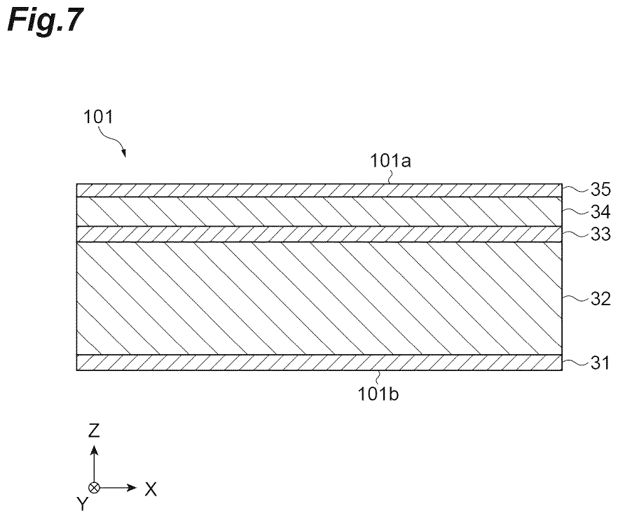

Next, an example of a manufacturing procedure of the sound-wave generating device 1 according to the present embodiment will be described with reference to FIG. 7 to FIG. 14. FIG. 7 to FIG. 14 are longitudinal sectional views (or plan views) showing a manufacturing procedure of the sound-wave generating device 1 according to the present embodiment shown in FIG. 1.

First, as shown in FIG. 7, the SOI substrate is subjected to a thermal oxidation treatment. The SOI substrate includes the silicon substrate 32, the oxide film layer 33 formed on a front surface of the preceding, and the silicon layer 34 formed on a front surface of the preceding. By the thermal oxidation treatment, the silicon oxide film 35 is formed on the front surface of the silicon layer 34 on a side opposite to the oxide film layer 33, and a silicon oxide film 31 is formed on the front surface of the silicon substrate 32 on a side opposite to the oxide film layer 33. Thereby, a member to be processed 101 having one end face 101a (the upper surface of the silicon oxide film 35) and the other end face 101b (the lower surface of the silicon oxide film 31) facing opposite directions is prepared (preparing step). As described above, the preparing step includes a step of obtaining the member to be processed 101 by subjecting a SOI substrate to thermal oxidation. In the step of obtaining the member to be processed, a film thickness of the member to be processed 101 (specifically, film thicknesses of the silicon oxide film 31 and the silicon oxide film 35) by thermal oxidation may be controlled such that the free end side of the substrate 80 is formed to be warped downward (to hang down) in a state where each step is completed. Note that, the silicon substrate 32 and the oxide film layer 33 are portions constituting the supporting substrate 4, and the silicon layer 34 and the silicon oxide film 35 are portions constituting the vibrating film formation layer 6.

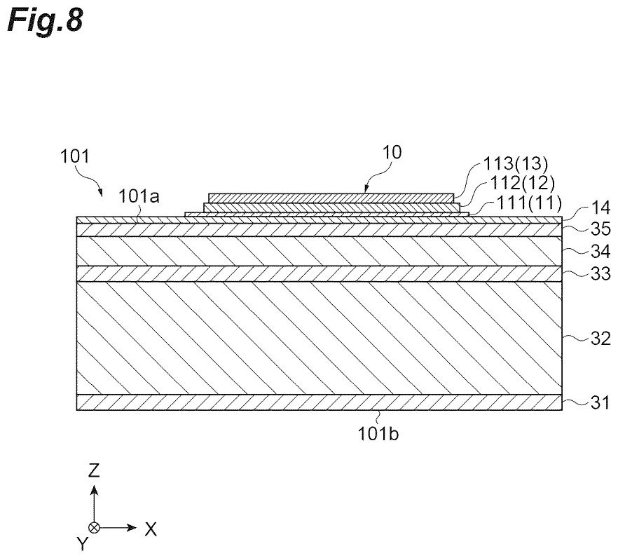

Subsequently, as shown in FIG. 8, the hydrogen barrier film 14 is formed on the one end face 101a of the member to be processed 101 (the upper surface of the silicon oxide film 35), and then a lower electrode film 111 as a material film of the lower electrode 11, a piezoelectric material film 112 as a material film of the piezoelectric film 12, and an upper electrode film 113 as a material film of the upper electrode 13 are formed in this order. Further, the upper electrode film 113, the piezoelectric material film 112, and the lower electrode film 111 are patterned by, for example, photolithography and etching in this order, thereby forming the upper electrode 13, the piezoelectric film 12, and the lower electrode 11. Thereby, the piezoelectric film 12 and electrodes (the lower electrode 11 and the upper electrode 13) are formed on the one end face 101a of the member to be processed 101 to form the piezoelectric element 10 (film forming step).

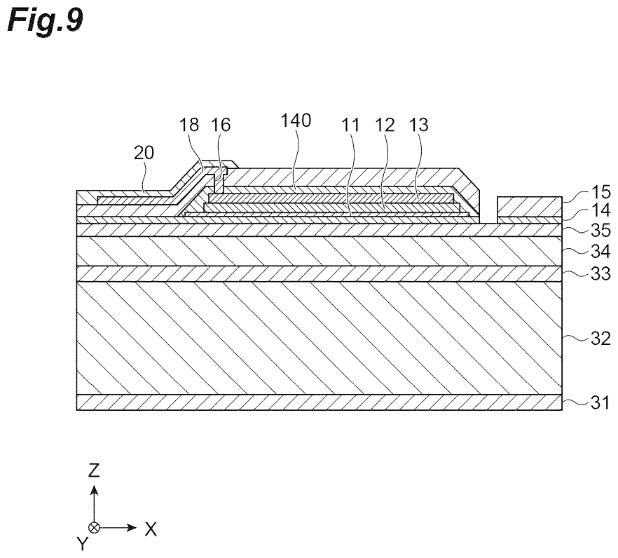

Subsequently, as shown in FIG. 9, the hydrogen barrier film 140 covering the exposed surface of the piezoelectric element 10 is formed. The hydrogen barrier film 140 is constituted, for example, of an alumina film. Then, the interlayer insulating film 15 is formed on the entire surface of the hydrogen barrier film 140. Further, the hydrogen barrier film 140 and the interlayer insulating film 15 are continuously etched to form the contact holes 16 and 17 (see FIG. 1). At this time, the interlayer insulating film 15 and the hydrogen barrier film 14 at the slit portion are also etched.

Further, a wiring film, which is a material film of the upper wiring 18 and the lower wiring 19, is formed on the interlayer insulating film 15 including the inside of the contact holes 16 and 17, and the wiring film is patterned by photolithography and etching, thereby forming the upper wiring 18 and the lower wiring 19 (see FIG. 1). Further, the passivation film 20 is formed on the interlayer insulating film 15 so as to cover the upper wiring 18 and the lower wiring 19. The interlayer insulating film 15 and the passivation film 20 are constituted, for example, of a TEOS film containing tetraethoxysilane (TEOS). The interlayer insulating film 15 and the passivation film 20 may be constituted, for example, of silicon nitride (SiN) or the like.

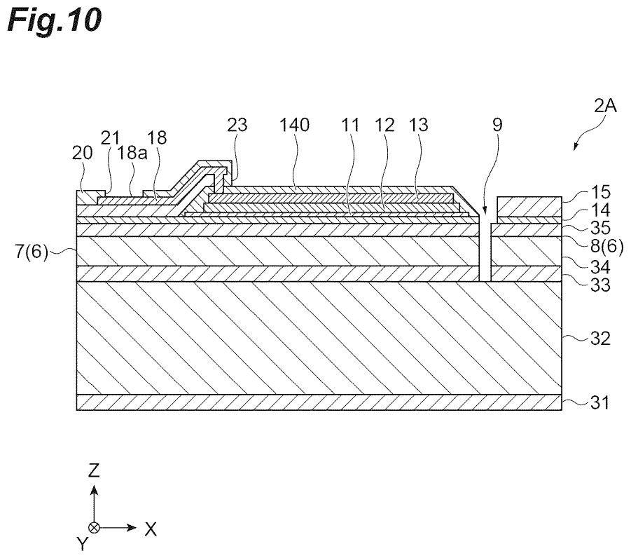

Subsequently, as shown in FIG. 10, the upper pad opening 21 exposing a part of the upper pad portion 18a and the lower pad opening 22 exposing a part of the lower pad portion 19a (see FIG. 1) are formed in the passivation film 20 by photolithography and etching. An opening 23 is formed in the interlayer insulating film 15 and the passivation film 20 by photolithography and etching. The opening 23 may not be formed or may be partially opened. Further, the slit 9 penetrating continuously through the vibrating film formation layer 6 (the silicon oxide film 35 and the silicon layer 34) and the oxide film layer 33 and reaching the silicon substrate 32 is formed by photolithography and etching. By forming the slit 9, the frame portion 8, which is a peripheral edge portion of the vibrating film formation layer 6, and the vibrating film 7, which is a central portion in the vibrating film formation layer 6, are obtained, and a work-in-process substrate assembly 2A before the cavity 5 is formed is obtained.

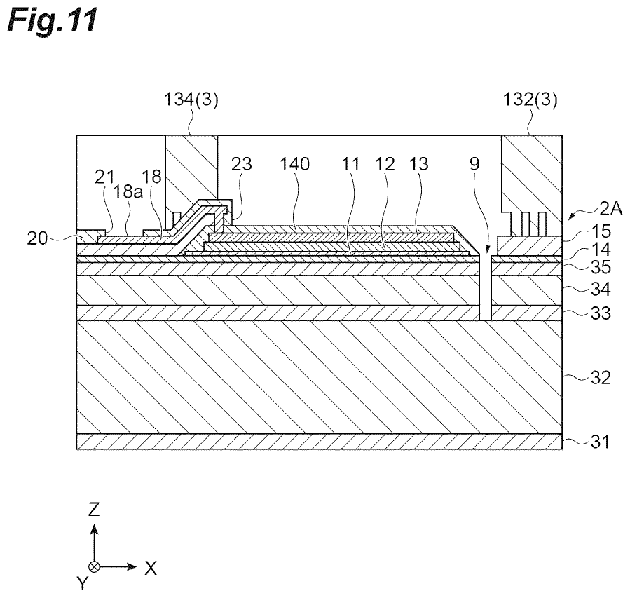

Subsequently, as shown in FIG. 11, an adhesive (not shown) is applied to a facing surface of the work-in-process substrate assembly 2A in the subframe 3, and the subframe 3 is fixed to the work-in-process substrate assembly 2A.

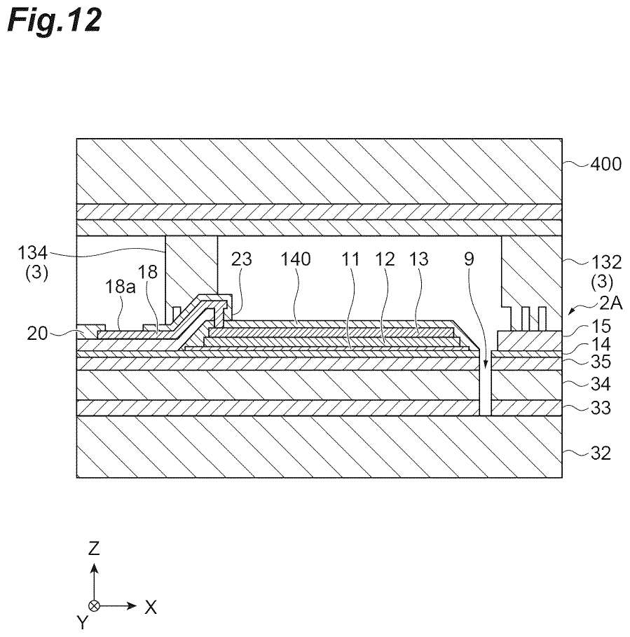

Subsequently, as shown in FIG. 12, a support substrate 400 is temporarily attached to the upper surface of the subframe 3, and the silicon oxide film 31, which is the other end face of the work-in-process substrate assembly 2A (the member to be processed after film formation) and the silicon substrate 32 are subjected to polishing processing, whereby the silicon substrate 32 is thinned.

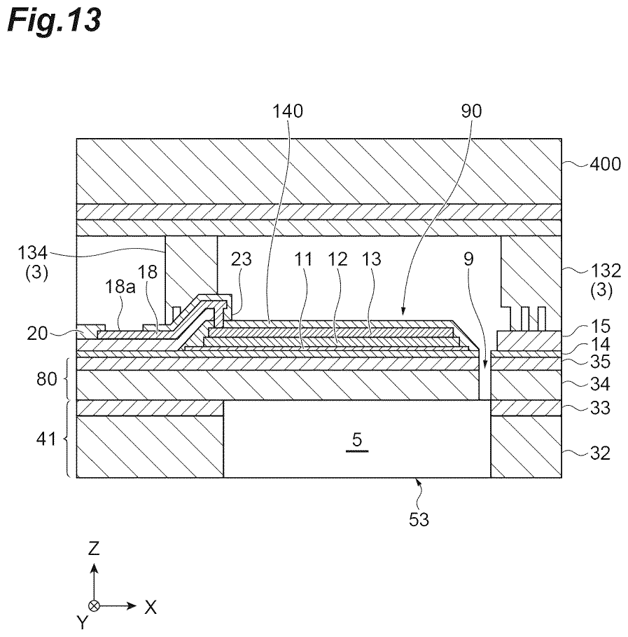

Further, as shown in FIG. 13, a resist mask (not shown) corresponding to a region where the cavity 5 is to be formed on the lower surface of the silicon substrate 32 (specifically, a region where the opening portion 53 is to be formed) is formed, and the silicon substrate 32 is etched from the lower surface. Thereby, the cavity 5 is formed, and the sound-wave generating device 1 including the piezoelectric film device 90 having the substrate 80, the support portion 41, and the piezoelectric film 12 is formed (forming step).

In a state where the steps up to this point have been completed, the substrate 80 is formed to be warped such that the second region 81y is located below the first region 81x (on the installation surface side in the vertical direction). For example, the film thickness of the silicon oxide film 35 in the thermal oxidation treatment may be controlled as described above, or the film thickness of the insulating film 30 on the vibrating film 7 may be controlled such that the free end side of the substrate 80 is held in a warped posture so as to hang down toward the fixed end side in this way. Alternatively, the residual film stress of the vibrating film formation layer 6, the piezoelectric element 10, and the insulating film 30 may be controlled by changing film formation conditions or partially adding an opening.

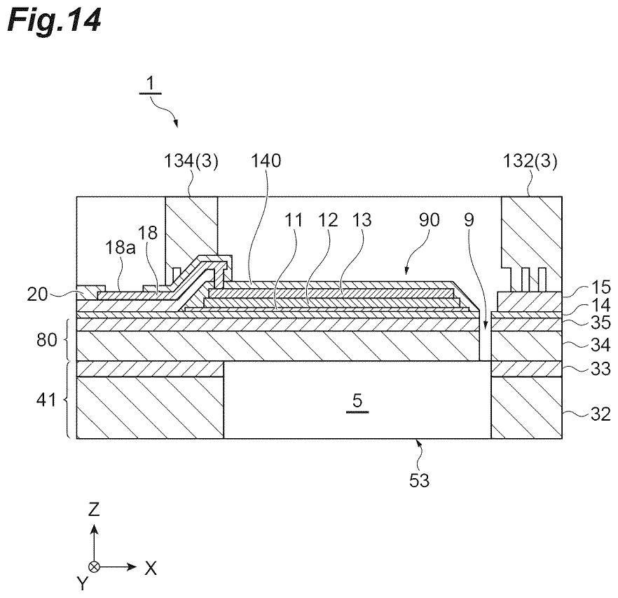

Finally, as shown in FIG. 14, the support substrate 400 is peeled, so that the piezoelectric film device 90 is enabled to operate, and the manufacturing of the sound-wave generating device 1 is completed.

Next, actions and effects of the piezoelectric film device 90, the sound-wave generating device 1, and a method for manufacturing the piezoelectric film device 90 according to the present embodiment will be described.

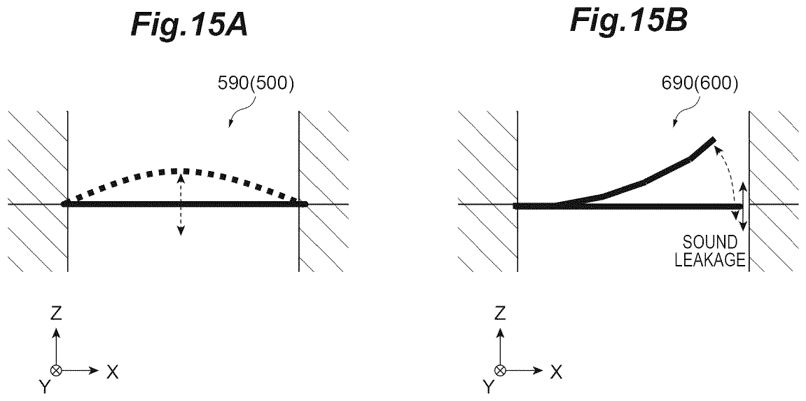

First, with reference to FIG. 15A and FIG. 15B, a piezoelectric film device 590 (FIG. 15A) included in a sound-wave generating device 500 according to a comparative example and a piezoelectric film device 690 (FIG. 15B) included in a sound-wave generating device 600 according to another comparative example will be described. FIG. 15A is a view describing the sound-wave generating device 500 according to a comparative example, and FIG. 15B is a view describing the sound-wave generating device 600 according to another comparative example. Note that, in FIG. 15A and FIG. 15B, for convenience of description, the configurations of the sound-wave generating devices 500 and 600 are extremely simplified, and illustration of configurations other than the schematically shown piezoelectric film devices 590 and 690 are omitted.

In the sound-wave generating device 500 shown in FIG. 15A, both end portions in the X direction of the piezoelectric film device 590 are constrained. Since such a piezoelectric film device 590 has no free end, no gap is generated at the time of vibration, and the influence of sound leakage can be suppressed. However, since both end portions in the X direction of the piezoelectric film device 590 are constrained, the vibration of the piezoelectric film device 590 is reduced.

On the other hand, in the sound-wave generating device 600 shown in FIG. 15B, the piezoelectric film device 590 has a cantilever structure, and only the front end portion in the X direction is a free end. Such a piezoelectric film device can increase vibration. However, in the piezoelectric film device 590 having a cantilever structure, since a gap is generated on the free end side, the influence of sound leakage may increase. In the piezoelectric film device 590 having a cantilever structure, a vibrating substrate is in a substantially horizontal state in a state where bias and drive voltages are not applied. When the bias voltage is applied from this state and the drive voltage is further applied, the piezoelectric film device 590 is greatly warped upward, so that the above-described gap is increased, and the influence of sound leakage increases. For this reason, a piezoelectric film device capable of suppressing sound leakage while sufficiently vibrating is required.

As shown in FIG. 3, the piezoelectric film device 90 according to the present embodiment includes the substrate 80 having the lower surface 81 and the upper surface 82 facing opposite directions, the support portion 41 supporting the lower surface 81 and fixed to the installation surface, and the piezoelectric film 12 provided on the upper surface 82 and displaced in the vertical direction together with the substrate 80 in response to application of a bias voltage and a drive voltage, in which the substrate 80 has the first region 81x supported by the support portion 41 and the second region 81y not supported by the support portion 41 as regions of the lower surface 81, and in a state where the bias voltage and the drive voltage are not applied, the substrate 80 is formed to be warped such that the second region 81y is located closer to the installation surface (lower side) than the first region 81x.

As described above, in a case where the substrate is in a horizontal state in a state where the bias voltage is not applied, when the bias voltage is applied thereafter, the warpage gap of the substrate upward increases. Further, when the drive voltage is applied with this state as a reference, a state where the gap is large is maintained, and the influence of sound leakage increases. In this regard, since the free end side of the substrate 80 is configured to hang downward in a state where the bias voltage and the drive voltage are not applied as in the piezoelectric film device 90, when the bias voltage is applied thereafter, the substrate 80 is displaced upward, and depending on the setting of the bias voltage, for example, a substantially horizontal state of the substrate 80 can be set as a reference (a state where the bias voltage is applied). Since the state where the substrate 80 is horizontal is a state where the gap is the smallest (see FIG. 4), the influence of sound leakage can be suppressed in the piezoelectric film device 90 having a cantilever structure by applying the drive voltage with this state as a reference. That is, the piezoelectric film device 90 according to the present embodiment can suppress the influence of sound leakage as compared with a general piezoelectric film device having a cantilever structure (the piezoelectric film device 690 in which the substrate is substantially horizontal in a state where the bias voltage is not applied). Further, according to the piezoelectric film device 90 having a cantilever structure, it is possible to increase vibration as compared with the piezoelectric film device 590 and the like in which both end portions are constrained. As described above, the piezoelectric film device 90 according to the present embodiment can suppress sound leakage while sufficiently vibrating.

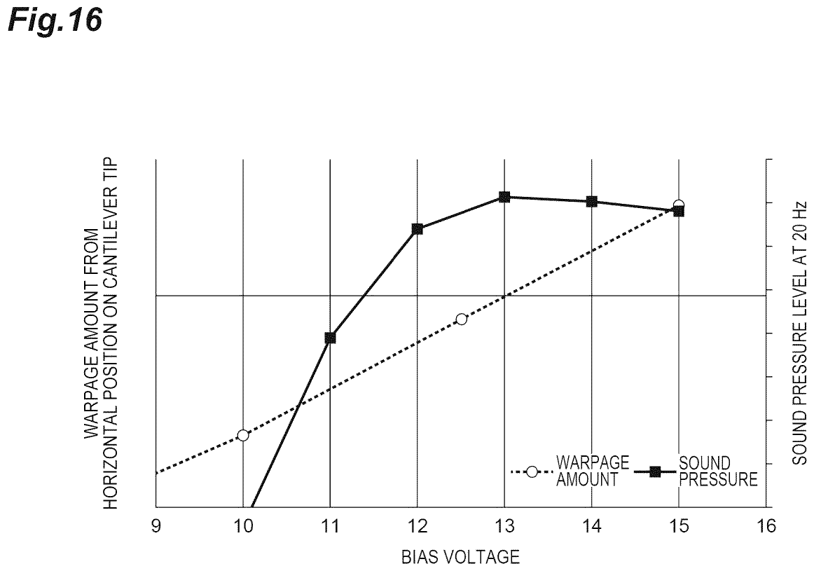

With reference to FIG. 16, the description will be given of a case where sound leakage is most suppressed and the sound pressure level is increased when the substrate 80 is in a horizontal state at the time of applying a bias voltage. FIG. 16 is a view showing an example of a sound pressure level according to a state at the time of applying a bias voltage. Since sound leakage is most affected by low sound, a sound pressure level of 20 Hz is used as an index here. In FIG. 16, the horizontal axis represents the bias voltage, the vertical axis (left) represents the warpage amount from the horizontal position on the free end side of the piezoelectric film device 90 having a cantilever structure, and the vertical axis (right) represents the sound pressure level at a low sound of 20 Hz. In an example shown in FIG. 16, in a case where the bias voltage is 13 V and the warpage amount on the free end side of the piezoelectric film device 90 is 0 (that is, horizontal), the sound pressure level is the maximum (sound leakage is minimum). As described above, it can be said that sound leakage is most suppressed and the sound pressure level is increased when the substrate 80 is in a horizontal state.

In a state where a bias voltage and a drive voltage are not applied, the difference in position between the first region 81x and the second region 81y in the vertical direction may be equal to or larger than the thickness of the silicon layer 34 constituting the substrate 80, or may be 100 μm or more and 500 μm or less. By setting the amount of sag to this extent, the substrate 80 can be appropriately brought into a horizontal state at the time of applying a bias voltage.

In a state where a bias voltage is applied and a drive voltage is not applied, the difference in position between the first region 81x and the second region 81y in the vertical direction may be equal to or less than the thickness of the substrate 80 in the vertical direction. According to such a configuration, since the substrate 80 is in a substantially horizontal state at the time of applying a bias voltage, sound leakage can be appropriately suppressed.

In a state where a bias voltage is applied and a drive voltage is not applied, the difference in position between the first region 81x and the second region 81y in the vertical direction may be 50 μm or less. According to such a configuration, since the substrate 80 is in a substantially horizontal state at the time of applying a bias voltage, sound leakage can be appropriately suppressed.

At the time of applying the drive voltage, the bias voltage may be a fixed value. Thereby, the piezoelectric film device 90 can be stably operated under preset conditions.

As shown in FIG. 1, the sound-wave generating device 1 according to the present embodiment includes one piezoelectric film device 90 described above. Since such a sound-wave generating device 1 includes the above-described piezoelectric film device 90, sound leakage can be suppressed while sufficiently vibrating the piezoelectric film device 90.

The method for manufacturing the piezoelectric film device 90 according to the present embodiment includes a step of preparing the member to be processed 101 having one end face 101a and the other end face 101b facing opposite directions, a step of forming the piezoelectric film 12 and electrodes (the upper electrode 13 and the lower electrode 11) on the one end face 101a of the member to be processed 101, and a step of processing the silicon oxide film 31 as the other end face of the member to be processed 101 after film formation and the silicon substrate 32 to form the substrate 80 and the support portion 41, in which in a state where each step is completed, the substrate 80 is formed to be warped such that the second region 81y is located closer to the installation surface side (lower side) than the first region 81x. According to such a manufacturing method, the piezoelectric film device 90 exhibiting the above-described action can be appropriately manufactured.

The preparing step may include a step of obtaining the member to be processed 101 by subjecting a SOI substrate to thermal oxidation, and in the step of obtaining the member to be processed, a film thickness of the member to be processed 101 by thermal oxidation is controlled such that the substrate 80 is formed to be warped in a state where each step is completed. According to such a manufacturing method, the piezoelectric film device 90 having the substrate 80 formed to be warped downward can be easily manufactured by film thickness control in thermal oxidation.

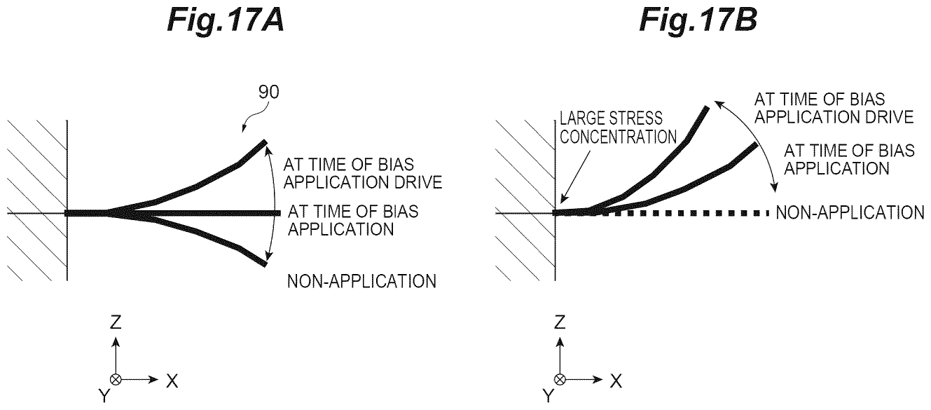

Note that, actions and effects of the sound-wave generating device 1 according to the present embodiment are not limited to the above-described contents. For example, the sound-wave generating device 1 according to the present embodiment can improve fracture resistance as compared with the piezoelectric film device having a cantilever structure according to the comparative example. FIGS. 17A and 17B are views describing additional actions and effects (improvement in fracture resistance) of the sound-wave generating device 1 according to the present embodiment. FIG. 17A schematically shows an operation of the piezoelectric film device 90 having a cantilever structure according to the present embodiment. FIG. 17B schematically shows an operation of a piezoelectric film device having a cantilever structure according to a comparative example. As described above, the state of the piezoelectric film device includes three states: a non-application state (a bias voltage and a drive voltage are not applied), a bias voltage application state (a bias voltage is applied and a drive voltage is not applied), and a bias application drive state (a bias voltage and a drive voltage are applied). As shown in FIG. 17B, when the substrate of the piezoelectric film device is in a horizontal state at the time of non-application, the substrate warps upward in the subsequent bias voltage application state, and the substrate further warps upward in the subsequent bias application drive state. Thereby, stress concentrates at the fixed end of the piezoelectric film device, and the piezoelectric film device may be broken depending on the drive voltage.

In this regard, as shown in FIG. 17A, in the piezoelectric film device 90 according to the present embodiment, since the free end side of the piezoelectric film device 90 hangs downward in the non-application state as described above, the warpage amount of the substrate 80 is reduced as compared with the comparative example described above even in the bias voltage application state and the bias application drive state thereafter. Therefore, stress concentration at the fixed end is alleviated, and destruction of the piezoelectric film device depending on the drive voltage can be appropriately suppressed.

Although the embodiment according to the present disclosure has been described above, the present disclosure is not limited to the above embodiment. For example, in the above embodiment, it has been described that the sound-wave generating device 1 includes one piezoelectric film device 90, but the configuration of the sound-wave generating device is not limited thereto. The sound-wave generating device may include a plurality (for example, a pair) of piezoelectric film devices.

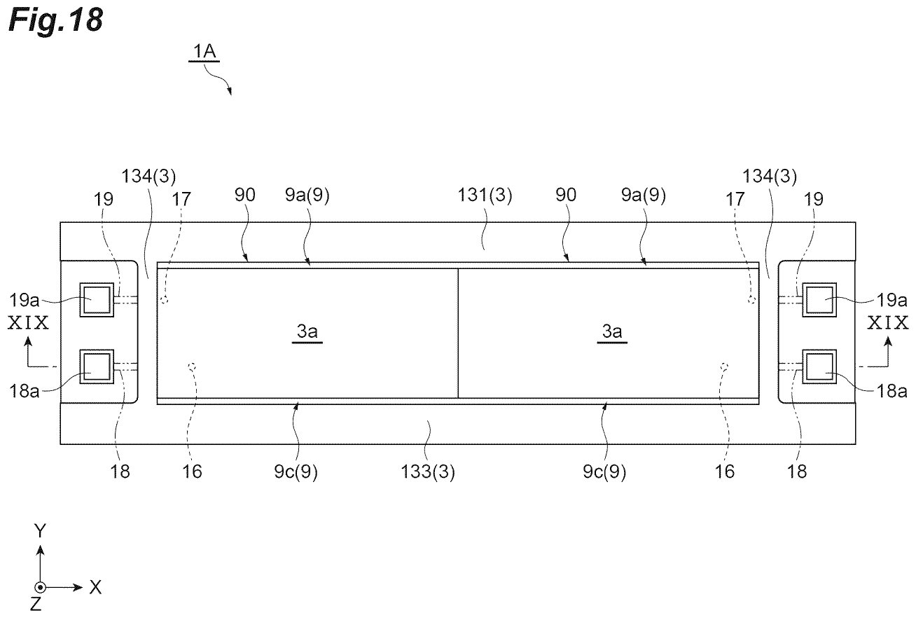

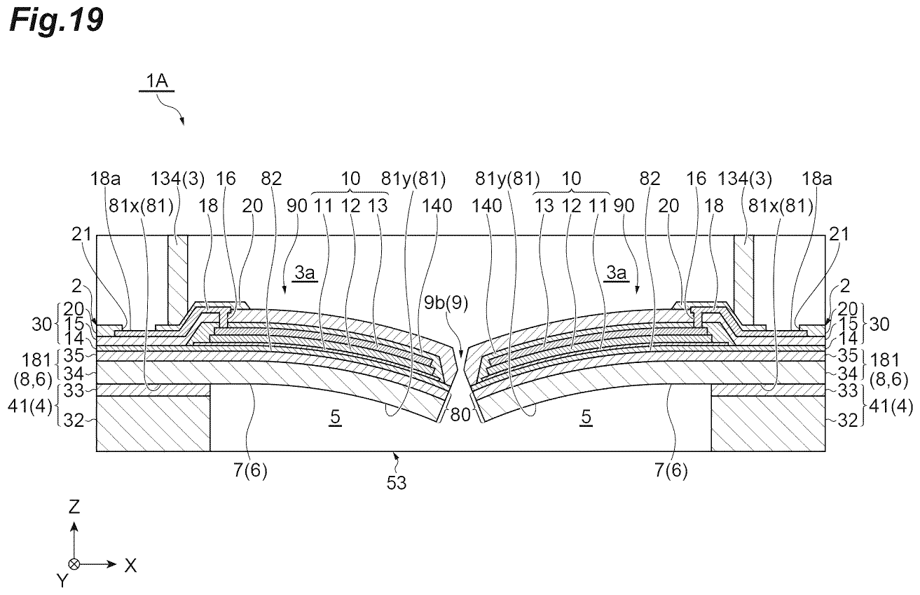

FIG. 18 is a plan view of a sound-wave generating device 1A according to a modification example. FIG. 19 is a longitudinal sectional view of the sound-wave generating device 1A taken along line XIX-XIX in FIG. 18. As shown in FIG. 18 and FIG. 19, the sound-wave generating device 1A includes two (a pair of) piezoelectric film devices 90 and 90. The configuration of the piezoelectric film device 90 may be as described above. For example, the pair of the piezoelectric film devices 90 and 90 is disposed such that free end sides face each other.

Furthermore, an application example of the piezoelectric film device is not limited to the sound-wave generating device (speaker or ultrasonic transducer), and may be, for example, other various transducers, a MEMS mirror, an inkjet head, or the like.

Furthermore, in the above embodiment, the description has been made in which the sound-wave generating device 1 includes the substrate assembly 2 and the subframe 3; however, the present disclosure is not limited thereto, and the sound-wave generating device may not include the subframe.

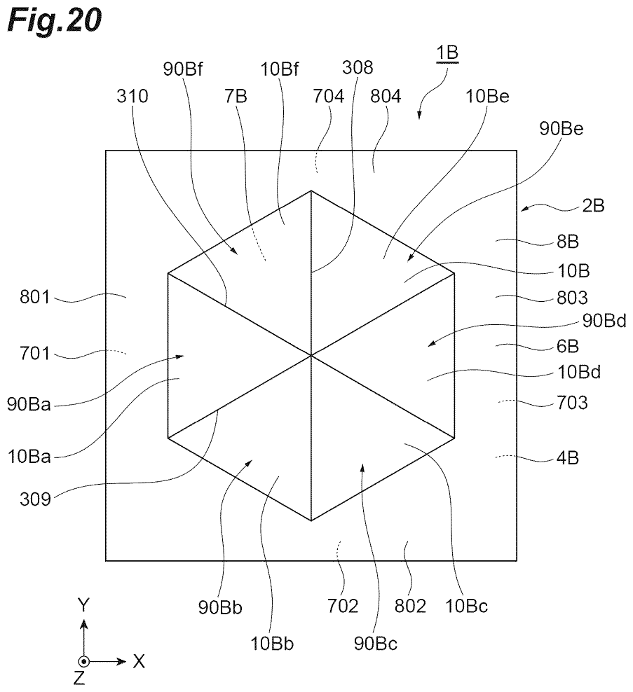

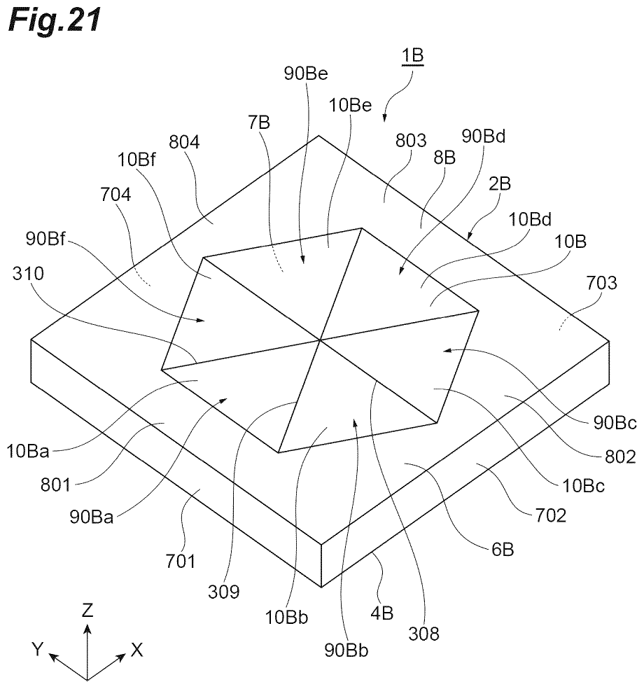

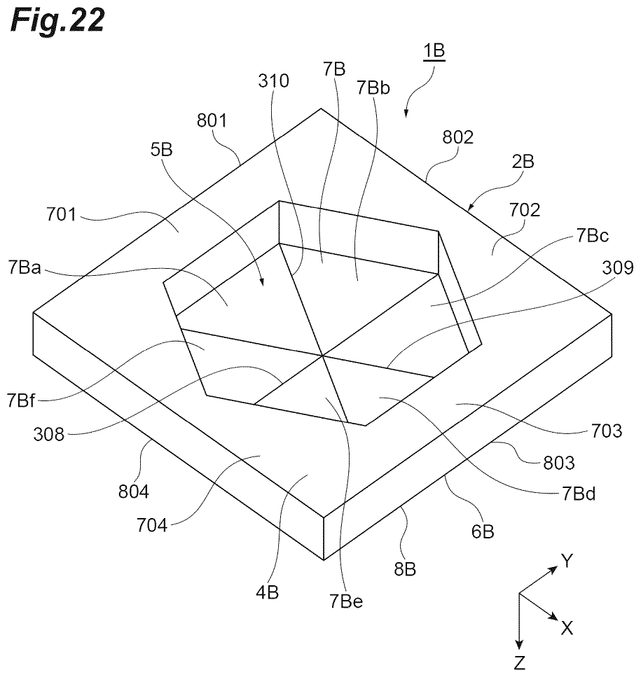

FIG. 20 is a plan view of a sound-wave generating device 1B according to a modification example. FIG. 21 is a perspective view of the sound-wave generating device 1B shown in FIG. 20 as viewed from above. FIG. 22 is a perspective view of the sound-wave generating device 1B shown in FIG. 20 as viewed from below. The sound-wave generating device 1B does not include a subframe, and includes only a substrate assembly 2B. The substrate assembly 2B includes a supporting substrate 4B, a vibrating film formation layer 6B, and a piezoelectric element 10B.

The supporting substrate 4B has a quadrilateral shape (substantially rectangular shape) in plan view. The supporting substrate 4B is made, for example, from a part of a SOI substrate. The supporting substrate 4B may include a silicon substrate and an oxide film layer. The supporting substrate 4B has a cavity (hollow space) 5B having a regular hexagonal shape in plan view at a central portion thereof (see FIG. 22). The cavity 5B has, for example, a hexagonal columnar shape. The supporting substrate 4B has a first portion 701, a second portion 702, a third portion 703, and a fourth portion 704 provided to surround the cavity 5B. The first portion 701 and the third portion 703 extend along the Y direction so as to sandwich the cavity 5B therebetween in the X direction. The second portion 702 and the fourth portion 704 extend along the X direction so as to sandwich the cavity 5B therebetween in the Y direction.

The vibrating film formation layer 6B is formed on the supporting substrate 4B. The vibrating film formation layer 6B may be constituted of a laminated film in which the silicon layer and the silicon oxide film are laminated. The vibrating film formation layer 6B includes a vibrating film 7B facing the cavity 5B and a frame portion 8B formed to surround the cavity 5B in plan view. The vibrating film 7B has a regular hexagonal shape substantially similar to the cavity 5B in plan view. The frame portion 8B includes a first frame 801, a second frame 802, a third frame 803, and a fourth frame 804. The first frame 801 is supported by the first portion 701. The second frame 802 is supported by the second portion 702. The third frame 803 is supported by the third portion 703. The fourth frame 804 is supported by the fourth portion 704.

The piezoelectric element 10B is formed to be disposed on the vibrating film formation layer 6B, specifically, on the vibrating film 7B. The piezoelectric element 10B may include a lower electrode formed on the vibrating film 7B, a piezoelectric film formed on the lower electrode, and an upper electrode formed on the piezoelectric film.

Here, in the sound-wave generating device 1B, slits 308, 309, and 310 penetrating through the piezoelectric element 10B and the vibrating film 7B are formed. The slit 308 extends along the Y direction. Each of the slits 309 and 310 extends so that the region of the piezoelectric element 10B is divided into six equal parts in consideration of an extending direction of the slit 308. That is, each of the slits 308, 309, and 310 extends so that the region of the piezoelectric element 10B is divided into six equal parts. Since such slits 308 and 309 are formed, the piezoelectric element 10B is separated into six piezoelectric elements 10Ba to 10Bf, and the vibrating film 7B is separated into six vibrating films 7Ba to 7Bf. Thereby, the sound-wave generating device 1B includes six piezoelectric film devices 90Ba to 90Bf.

Also in each of such piezoelectric film devices 90Ba to 90Bf, in a state where a bias voltage and a drive voltage are not applied, since the “substrate” is “formed to be warped such that the second region is located closer to the installation surface side than the first region”, the same actions and effects as those of the configuration according to the embodiment can be achieved.

Various embodiments of the present disclosure can be defined as the following clauses.

### (Clause 1, Embodiment, FIG. 3)

A piezoelectric film device comprising:
a substrate having a first surface and a second surface facing opposite directions;
a support portion supporting the first surface and fixed to an installation surface; and
a piezoelectric film provided on the second surface and displaced in a first direction together with the substrate in response to application of a bias voltage and a drive voltage, wherein
the substrate has a first region supported by the support portion and a second region not supported by the support portion as regions of the first surface, and
in a state where the bias voltage and the drive voltage are not applied, the substrate is formed to be warped such that the second region is located closer to the installation surface side in the first direction than the first region.

### (Clause 2, Embodiment, FIG. 3)

The piezoelectric film device according to clause 1, wherein in a state where the bias voltage and the drive voltage are not applied, a difference in position between the first region and the second region in the first direction is equal to or larger than a thickness of an active layer constituting the substrate in the first direction.

### (Clause 3, Embodiment, FIG. 3)

The piezoelectric film device according to clause 1 or 2, wherein in a state where the bias voltage and the drive voltage are not applied, a difference in position between the first region and the second region in the first direction is 100 μm or more and 500 μm or less.

### (Clause 4, Embodiment, FIG. 4)

The piezoelectric film device according to any one of clauses 1 to 3, wherein in a state where the bias voltage is applied and the drive voltage is not applied, a difference in position between the first region and the second region in the first direction is equal to or less than a thickness of the substrate in the first direction.

### (Clause 5, Embodiment, FIG. 4)

The piezoelectric film device according to any one of clauses 1 to 4, wherein in a state where the bias voltage is applied and the drive voltage is not applied, the difference in position between the first region and the second region in the first direction is 50 μm or less.

### (Clause 6, Embodiment)

The piezoelectric film device according to any one of clauses 1 to 5, wherein the bias voltage has a fixed value at the time of applying the drive voltage.

### (Clause 7, Embodiment, FIG. 3)

A transducer comprising the piezoelectric film device according to any one of clauses 1 to 6.

### (Clause 8, Embodiment, FIG. 7 to FIG. 14)

A method for manufacturing the piezoelectric film device according to any one of clauses 1 to 6, the method comprising:
a step of preparing a member to be processed having one end face and the other end face facing opposite directions;
a step of forming the piezoelectric film and an electrode on the one end face of the member to be processed; and
a step of processing the other end face of the member to be processed after film formation to form the substrate and the support portion, wherein
in a state where each step is completed, the substrate is formed to be warped such that the second region is located closer to the installation surface side in the first direction than the first region.

### (Clause 9, Embodiment, FIG. 7)

The method according to clause 8, wherein
the preparing step includes a step of obtaining the member to be processed by subjecting a substrate containing silicon to thermal oxidation, and
in the step of obtaining the member to be processed, a film thickness of the member to be processed by thermal oxidation is controlled such that the substrate is formed to be warped in a state where each step is completed.
1, 1A, 1B Sound-wave generating device
2, 2B Substrate assembly
2A Work-in-process substrate assembly
3 Subframe
3a Housing recess
3b Through hole
4, 4B Supporting substrate
5, 5B Cavity
6, 6B Vibrating film formation layer
7, 7B (7Ba to 7Bf) Vibrating film
8, 8B Frame portion
9 Slit
9a First portion
9b Second portion
9c Third portion
10, 10B (10Ba to 10Bf) Piezoelectric element
11 Lower electrode
12 Piezoelectric film
13 Upper electrode
14 Hydrogen barrier film
15 Interlayer insulating film
16, 17 Contact hole
18 Upper wiring
18a Upper pad portion
19 Lower wiring
19a Lower pad portion
20 Passivation film
21 Upper pad opening
22 Lower pad opening
23 Opening
30 Insulating film
31 Silicon oxide film
32 Silicon substrate
33 Oxide film layer
34 Silicon layer
35 Silicon oxide film
41 Support portion
42 First portion
43 Second portion
44 Third portion
53 Opening portion
80 Substrate
81 Lower surface
81x First region
81y Second region
82 Upper surface
90, 90Ba to 90Bf Piezoelectric film device
101 Member to be processed
101a One end face
101b Other end face
111 Lower electrode film
112 Piezoelectric material film
113 Upper electrode film
131 First portion
132 Second portion
133 Third portion
134 Connecting portion
140 Hydrogen barrier film
181 Support frame
182 First portion
183 Second portion
184 Third portion
308 Slit
309 Slit
310 Slit
400 Support substrate
500, 600 Sound-wave generating device
590, 690 Piezoelectric film device
701 First portion
702 Second portion
703 Third portion
704 Fourth portion
801 First frame
802 Second frame
803 Third frame
804 Fourth frame

What is claimed is:

1. A piezoelectric film device comprising:
a substrate having a first surface and a second surface facing opposite directions;
a support portion supporting the first surface and fixed to an installation surface; and
a piezoelectric film provided on the second surface and displaced in a first direction together with the substrate in response to application of a bias voltage and a drive voltage, wherein
the substrate has a first region supported by the support portion and a second region not supported by the support portion as regions of the first surface, and
in a state where the bias voltage and the drive voltage are not applied, the substrate is formed to be warped such that the second region is located closer to the installation surface side in the first direction than the first region.

2. The piezoelectric film device according to claim 1, wherein in a state where the bias voltage and the drive voltage are not applied, a difference in position between the first region and the second region in the first direction is equal to or larger than a thickness of an active layer constituting the substrate in the first direction.

3. The piezoelectric film device according to claim 1, wherein in a state where the bias voltage and the drive voltage are not applied, a difference in position between the first region and the second region in the first direction is 100 μm or more and 500 μm or less.

4. The piezoelectric film device according to claim 1, wherein in a state where the bias voltage is applied and the drive voltage is not applied, a difference in position between the first region and the second region in the first direction is equal to or less than a thickness of the substrate in the first direction.

5. The piezoelectric film device according to claim 4, wherein in a state where the bias voltage is applied and the drive voltage is not applied, the difference in position between the first region and the second region in the first direction is 50 μm or less.

6. The piezoelectric film device according to claim 1, wherein the bias voltage has a fixed value at the time of applying the drive voltage.

7. A transducer comprising the piezoelectric film device according to claim 1.

8. A method for manufacturing the piezoelectric film device according to claim 1, the method comprising:
a step of preparing a member to be processed having one end face and the other end face facing opposite directions;
a step of forming the piezoelectric film and an electrode on the one end face of the member to be processed; and
a step of processing the other end face of the member to be processed after film formation to form the substrate and the support portion, wherein
in a state where each step is completed, the substrate is formed to be warped such that the second region is located closer to the installation surface side in the first direction than the first region.

9. The method according to claim 8, wherein
the preparing step includes a step of obtaining the member to be processed by subjecting a substrate containing silicon to thermal oxidation, and
in the step of obtaining the member to be processed, a film thickness of the member to be processed by thermal oxidation is controlled such that the substrate is formed to be warped in a state where each step is completed.
